(19) United States
(12) Patent Application Publication
(10) Pub. No.: US 2018/0050230 A1
(43) Pub. Date: Feb. 22, 2018

(54) ELECTRICAL WALL OUTLET FIRE DETECTION SYSTEM

(71) Applicant: Marc TOLAND, Stamford, CT (US)

(72) Inventor: Marc TOLAND, Stamford, CT (US)

(21) Appl. No.: 15/239,377

(22) Filed: Aug. 17, 2016

(51) Int. Cl. A62C 3/16; H04W 4/00; H04M 1/725; H05K 5/02

(52) U.S. Cl. CPC A62C 3/16; H05K 5/0247; H04M 1/72527; H04W 4/005

(57) ABSTRACT

An electrical outlet has an integrated environment detector such as a fire detector. The electrical outlet has an electrical outlet receptacle with one or more electrical sockets. The electrical outlet receptacle is adapted to be disposed in an electrical outlet box. Advantageously, carbon monoxide sensor along with at least one additional sensor such as heat, particle and smoke are disposed within or integral with the electrical receptacle. A wireless transmitter is operatively associated with the carbon monoxide sensor and the at least one additional sensor for identifying an environmental event such as a fire event.

### FIELD OF THE INVENTION

The present invention relates to an electrical wall outlet with an environment detector and in particular an electrical wall outlet with integral fire detector.

### BACKGROUND OF THE INVENTION

Emergency detection systems such as fire detection systems alert occupants and emergency professionals of possible fire emergencies. Fire detection systems have been developed to place fire detectors in differing environments and for sensing different events that signify the presence of a fire. Some prior systems include smoke detectors, particle detectors and heat sensors, individually or possibly in combination, to detect a possible fire.

Traditional fire detectors are stand-alone devices that are either powered by battery or may be hardwired to a facility's electrical system.

### SUMMARY OF THE INVENTION

The present invention is directed to an electrical wall outlet with integrated or built-in environment detector such as a fire detector. Advantageously, the electrical outlet is adapted to be disposed in a conventional electrical outlet box. As a result, the present electrical outlet with an integrated fire detector can be easily installed in a residential or commercial building, both new construction as well as use with an existing building. The electrical outlet has one or more electrical sockets. A carbon monoxide sensor and at least an additional sensor such as heat, particle, gas and smoke are disposed within or integral with the electrical outlet receptacle. A wireless transmitter is operatively associated with the carbon monoxide sensor and at least one of the additional sensors. In use, the electrical outlet fire detector sends a signal wirelessly to a remote alarm, monitoring station, or mobile electronic device such as a smart phone to alert one that a possible fire has been detected.

Advantageously, the combination of a carbon monoxide sensor along with an additional sensor such as heat, particle, gas and smoke allows for a more accurate identification of a fire event. For example, a computer processor is disposed within the electrical outlet fire detector and associated with the sensors to identify a fire event based on input from the carbon monoxide sensor and the other sensors. Alternatively, a computer processor can be located remote from the sensors (i.e., away from the outlet) and operatively associated with the sensors via a wireless signal or a computer network connection (e.g., a local area network (LAN), wide area network (WAN) or the internet). As with a processor which can be located in the outlet, the remote processor includes logic for identifying a fire event based on information generated from the carbon monoxide sensor and the additional sensor(s).

The present invention, in one form thereof, is directed to an electrical wall outlet with integrated fire detector. The wall outlet has an electrical outlet receptacle with one or more electrical sockets. The electrical outlet receptacle is adapted to be disposed in an electrical outlet box. A carbon monoxide sensor is disposed within or integral with the electrical receptacle. At least one additional sensor selected from the group consisting of heat, particle, gas and smoke is also disposed within or integral with the electrical receptacle. A wireless transmitter is operatively associated with the carbon monoxide sensor and the at least one additional sensor. In specific, further advantageous form, the electrical outlet has a computer network connection associated with the carbon monoxide sensor.

The present invention, in another form thereof is directed to a system for detecting fire. The system has an electrical outlet receptacle with one or more electrical sockets. The electrical outlet is adapted to be disposed in an electrical outlet box. A carbon monoxide sensor and at least an additional sensor selected from the group consisting of heat, particle, gas and smoke is disposed within or is integral with the electrical receptacle. A wireless transmitter is operatively associated with the carbon monoxide sensor and at least one additional sensor. An alert device has a receiver to wirelessly connect the alert device to the carbon monoxide sensor and the at least one additional sensor via the wireless transmitter.

The present invention in another form thereof is directed to an electrical wall outlet with integrated environment detector. The wall outlet has a housing adapted to be disposed in an electrical outlet box. One or more electric sockets are disposed within the housing. A at least one sensor selected from the group consisting of carbon monoxide, heat, particle, gas and smoke are disposed within or integral with the housing. A wireless transmitter is operatively associated with the sensor(s). In one further advantageous form, a computer processor is operatively associated with the sensor(s), to identify the presence of an environmental event such as a fire, gas leak, etc.

### BRIEF DESCRIPTION OF THE DRAWINGS

FIG. 1 is a schematic showing a system for detecting an environmental event such as a fire in accordance with the present invention.

FIG. 2 is an electrical outlet with integrated fire detector in accordance with the present invention.

FIG. 3 is an electrical outlet box into which the electrical outlet with integrated fire detector of FIG. 2 can be disposed.

FIG. 4 is a front elevation view of the electrical outlet of FIG. 2 disposed within the electrical outlet box of FIG. 3.

FIG. 5 is a cross section view of the electrical outlet box of FIG. 4 taken along line 5-5.

FIG. 6 is a schematic showing aspects of the electrical outlet with integrated fire detector in accordance with the present invention.

### DETAILED DESCRIPTION

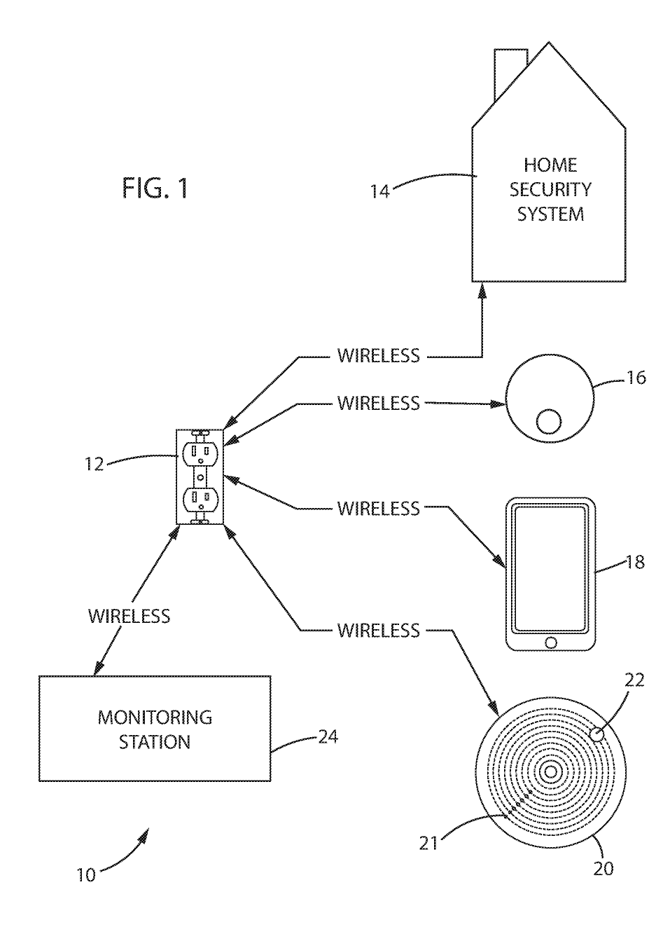

The present invention will now be described with reference to the figures. FIG. 1 is a schematic showing fire alert system 10 which includes an electrical outlet 12 having an integrated fire detector. The electrical outlet 12 wirelessly connects to various receivers or devices including a home security system 14, smoke detector 16, an electronic mobile device 18, a remote alarm 20 and a monitoring station 24. The receivers, e.g. smoke detector 16, a remote alarm 20 and a monitoring station 24 can have their own, respective environment sensors such as a carbon monoxide sensor, heat, particle, gas and smoke. Although only one electrical outlet 12 is shown in FIG. 1 for simplifying the schematic, the system 10 can have a number of outlets 12 located throughout a building to act as a network of fire detectors.

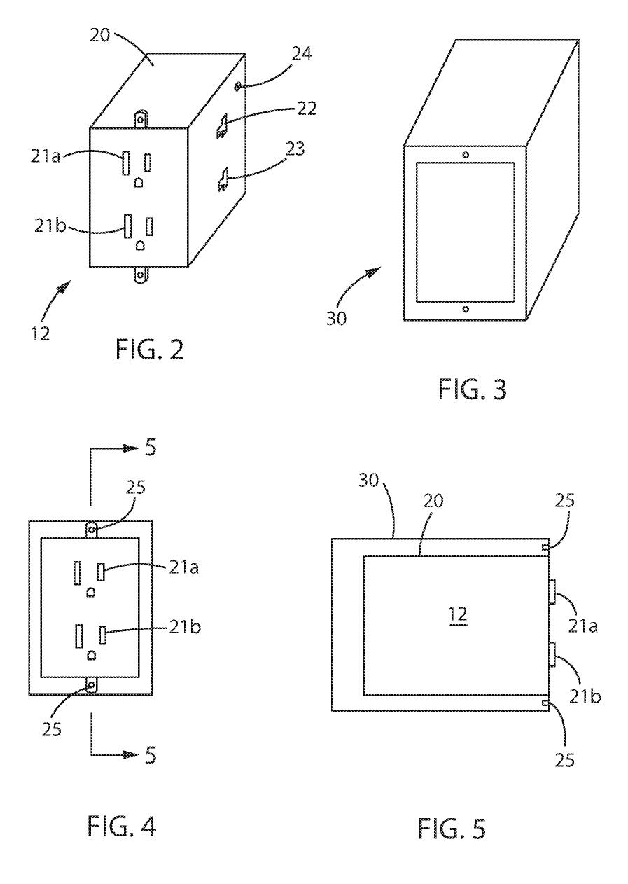

Referring now to FIGS. 2-5 along with FIG. 1, the electrical outlet 12 has a housing or receptacle body 20 which holds or houses two electrical sockets 21a, 21b. Alternatively, if desired, the electrical outlet can include additional sockets, a light switch or other conventional electrical outlet receptacle devices including but not limited to switches, ground fault interrupters (GFI), etc.

Terminals 22, 23 are used to connect the electrical outlet receptacle 20 to current in a building such as a 120/220 supply with a ground wire connected to terminal 24.

Advantageously, the electrical outlet receptacle 20 can be disposed within a conventional electrical box 30 (FIG. 3). FIGS. 4 and 5 show a typical installation of the electrical outlet receptacle 20 installed in the electrical outlet box 30 and held in place by screws 25.

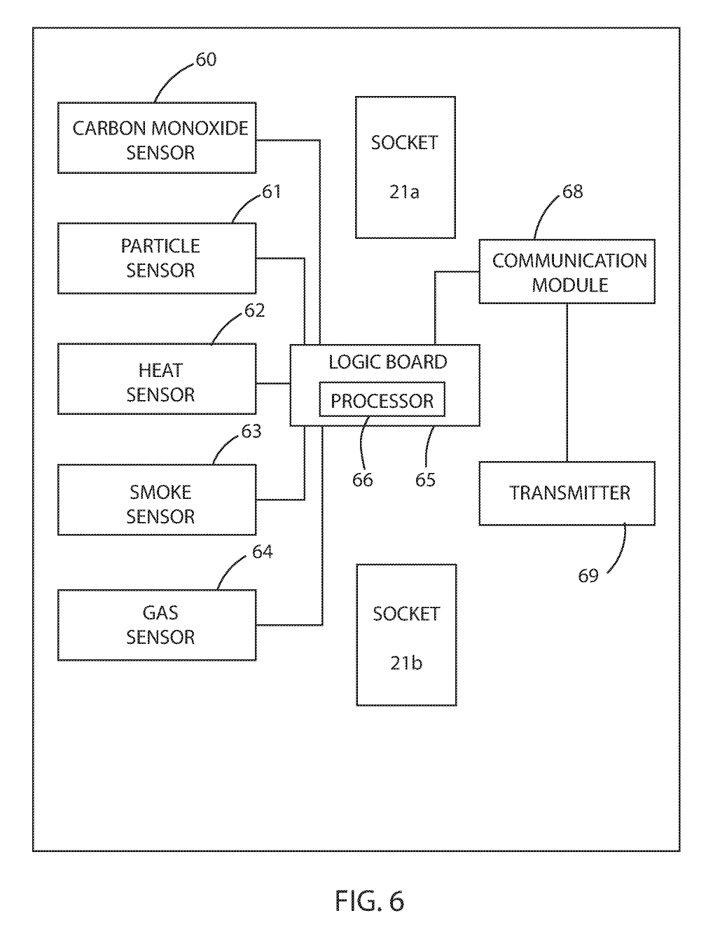

Referring now to FIG. 6, the electrical outlet 20 is shown as a schematic to simplify understanding of its integrated fire detector. Elements shown in FIG. 6 schematically are either disposed within the housing or receptacle 20 or may be disposed along an exterior surface of the housing or receptacle 20 as appropriate and desired in accordance with this disclosure. The electrical outlet 12 has several sensors including a carbon monoxide sensor 60, a particle sensor 61, a heat sensor 62, a smoke sensor 63, and gas sensor 64. The gas sensor 64 can be adapted to detect various environment gases, including but not limited to carbon dioxide, natural gas and other organic hydrocarbons, scents and odors. Advantageously, each of the sensors 60-64 are connected to a computer board 65 with computer processor 66. Processor 66 includes computer logic for identifying a possible fire event from signals received from the sensors 60-63. When processor 66 identifies a possible fire, the processor 66 sends a signal via communication module 68, via a wired connector or a wireless connection via wireless transmitter 69, indicating the identification of a possible fire or other environmental event.

Referring now to the communication module 68 in more detail, the communication module 68 transmits a wireless signal via transmitter 69 to a receiver which provides audible/visual/communication information to appropriate personal. A non-exclusive list of receivers include, but are not limited to the home security system 14, smoke detector 16, electronic mobile device 18, remote alarm 20 and monitoring station 24 (see, FIG. 1). The wireless communication may include any type of wireless transmission technology, including, but not limited to, WiFi, 3G, 2G, 2.5G, 4G, WiMax, BlueTooth. Some, but not all, possible communication networks that may comprise a computer network or be otherwise part of a system that includes a local area network (LAN), a wide area network (WAN), the Internet, a telephone line, a cable line, as well as an RF channel, an optical communications line, and a satellite communications link.

Alternatively or in addition to using the wireless transmitter 69, the communication module 68 can be directly wired to a computer network. For example, the communication module 68 can be hardwired connected to a local area network (LAN), wide area network (WAN) or the Internet.

Referring to FIG. 1 along with FIG. 6, the identification of a possible fire event can be received wirelessly by various receivers or devices including the home security system 14, smoke detector 16, electronic mobile device 18, remote alarm 20 and monitoring station 24. For example, the home security system 14, smoke detector 16, electronic mobile device 18, remote alarm 20 and monitoring station 24 have wireless receivers for receiving signals from the transmitter 69 for wireless communication between the electrical outlet 12 and the aforementioned receivers. The receivers can receive signals either directly from the transmitter 69 or wirelessly via a computer network operatively associated with the communication module 68 and/or transmitter 69. Alternatively, rather than receiving wireless signals, the receivers can be hardwired to a telecommunication or computer network operatively associated with the sensors of the outlet 12. Upon identification of a fire event, an appropriately adapted receiver can alert the fire department or other emergency personal of a possible dangerous event.

In alternative embodiments, the home security system 14, smoke detector 16, electronic mobile device 18, remote alarm 20 and monitoring station 22 have respective computer processors for receiving and processing information from the sensors in the electrical outlet 12. For example, the monitoring station 24 can have its own processor for processing data from the carbon monoxide sensor 60 and other sensors such as heat sensor 62 and smoke sensor 63 to identify a possible fire from the presence of detected carbon monoxide heat and smoke.

In use, when an environmental event such as a fire event is identified for example via processor 66 or respective processors in the receivers which receive data from the sensors in the electrical wall outlet via a wired connection or via transmitter 69, an alert is sent from the receiver to warn occupants and emergency personnel of the fire event. For example, remote alarm 20 has a speaker 21 and a light 22 to alert one of a fire event by producing an audible sound or light, respectively.

In another example, the monitoring station 24 can be remote from a building to which electrical outlets 12 are installed. The monitoring station 24 can include human personnel who receive and review data from the sensors (60-64) and alert the appropriate emergency personnel upon receipt of information from the sensors (60-64) in the electrical outlet 12. Alternatively, the monitoring station 24 can be completely automated and connected to a telephone line or other connection to remote emergency personnel to alert the emergency personnel that a possible fire event has been detected in the building. In addition, a location in the building of a fire event can be identified from data collected by the sensors (60-64) in the electrical outlets 12 deployed throughout a building.

It will now be clear to one of ordinary skill in the art that the present electrical outlet with integrated environment detector such as a fire detector has advantages and functions not found in prior fire detection systems. Having the detector integrated within an electrical outlet receptacle itself allows for easy installation in both new construction as well as retrofitting an existing building. In addition, integrating the detector within the electrical outlet allows for a compact product. Further, the use of a carbon monoxide sensor along with other sensors such as smoke, fire, heat, gas, etc., allows the present fire detector to be more sensitive to accurately identifying a fire event based on the presence of carbon monoxide along with smoke, particle, or heat present. In addition, communicating (advantageously wirelessly) between the sensors' location where carbon monoxide along with smoke, particle, gas or heat is detected, allows for deployment of a sensor at a location where a fire is likely to occur, such as in the proximity of a wall to detect a possible electrical fire, and then transmits the detection of the event for receipt by a wireless device at a remote location from the location where the event is detected. As a result, a central system such as a monitoring station or an electronic mobile device can be used to receive detection of a possible fire event remote from the actual location of the fire or other environmental event.

Although the invention has been described with respect to a preferred embodiment, it is to be understood that the invention is capable of numerous modifications and variations, apparent to those skilled in the art, without departing from the spirit and scope of the invention.

What is claimed is:

1. An electrical wall outlet with integrated fire detector, said wall outlet comprising:
an electrical outlet receptacle having one or more electrical sockets, the electrical outlet receptacle adapted to be disposed in an electrical outlet box;
a carbon monoxide sensor disposed within or integral with the electrical receptacle;
at least one additional sensor selected from the group consisting of heat, particle, and smoke disposed within the electrical receptacle; and
a wireless transmitter operatively associated with the carbon monoxide sensor and the at least one additional sensor.

2. The electrical wall outlet of claim 1 further comprising electrical terminals for connecting the electrical outlet to electrical wiring of a building for providing power to the one or more electrical sockets.

3. The electrical wall outlet of claim 2 wherein the carbon monoxide sensor is powered directly from electricity provided through the electrical terminals.

4. The electrical wall outlet of claim 1, further comprising a computer network connection associated with the carbon monoxide sensor.

5. The electrical wall outlet of claim 1, further comprising a computer processor operatively associated with the carbon monoxide sensor and the at least one other sensor, to identify presence of a fire.

6. A system for detecting fire, said system comprising:
an electrical outlet receptacle having one or more electrical sockets, the electrical outlet receptacle adapted to be disposed in an electrical outlet box;
a carbon monoxide sensor disposed within or integral with the electrical receptacle;
at least one additional sensor selected from the group consisting of heat, particle, and smoke disposed within the electrical receptacle;
a wireless transmitter operatively associated with the carbon monoxide sensor and the at least one additional sensor; and
an alert device having a receiver to wirelessly connect the alert device to the carbon monoxide sensor and the at least one additional sensor via the wireless transmitter.

7. The system of claim 6, wherein the alert device has a speaker for producing an audible sound.

8. The system of claim 6, wherein the alert device has a light source for emitting light.

9. The system of claim 6, further comprising a computer network connection associated with the carbon monoxide sensor.

10. The system of claim 9, wherein the computer network connection allows connectivity to a local area network.

11. The system of claim 9, wherein the computer network connection is allows connectivity to the Internet.

12. The system of claim 9, wherein the computer network connection permits alerts to be sent from the carbon monoxide sensor to a mobile communication device.

13. The system of claim 7, further comprising a smoke detector having a wireless receiver to connect wirelessly with the wireless transmitter.

14. The system of claim 6, a monitor station wirelessly connected to the carbon monoxide sensor.

15. The system of claim 6, further comprising an electrical outlet box into which the electrical outlet receptacle is disposed.

16. The system of claim 6, further comprising a computer processor operatively associated with the carbon monoxide sensor and the at least one other sensor, to identify presence of a fire.

17. The system of claim 6, wherein the alert device has its own sensor selected from the group consisting of carbon monoxide, heat, particle, gas and smoke.

18. An electrical wall outlet with integrated environment detector, said wall outlet comprising:
a housing adapted to be disposed in an electrical outlet box;
one or more electrical sockets within the housing;
at least one sensor selected from the group consisting of carbon monoxide, heat, particle, gas, and smoke, the at least one sensor being disposed within or integral with the housing; and
a wireless transmitter operatively associated with the at least one sensor.

19. The electrical wall outlet of claim 18, wherein the at least one sensor is the carbon monoxide sensor and a second sensor is selected from the remaining sensors from the group consisting of heat, particle, gas, and smoke.

20. The electrical wall outlet of claim 19, further comprising a computer processor operatively associated with the carbon monoxide sensor and the second sensor, to identify presence of a fire.

21. The electrical wall outlet of claim 18 further comprising electrical terminals for connecting the electrical outlet to electrical wiring of a building for providing power to the one or more electrical sockets.

22. The electrical wall outlet of claim 21, wherein the at least one sensor is powered directly from electricity provided through the electrical terminals.

23. The electrical wall outlet of claim 18, further comprising a computer network connection associated with the at least one sensor.

23. The electrical wall outlet of claim 22, wherein the computer network connection permits alerts to be sent from the at least one sensor to a mobile communication device.
